(19) United States
(12) Patent Application Publication
(10) Pub. No.: US 2025/0014858 A1
(43) Pub. Date: Jan. 9, 2025

(54) Correction Method and Correction Device

(71) Applicant: HITACHI HIGH-TECH CORPORATION, Minato-ku, Tokyo (JP)

(72) Inventors: Tomoaki YAMAZAKI, Tokyo (JP); Kei SAKAI, Tokyo (JP)

(21) Appl. No.: 18/710,251

(22) PCT Filed: Nov. 29, 2021
(86) PCT No.: PCT/JP2021/043525

§ 371 Date: May 15, 2024

(51) Int. Cl. H01J 37/21; H01J 37/153; H01J 37/22; H01J 37/26; H01J 37/28

(52) U.S. Cl. CPC H01J 37/21; H01J 37/153; H01J 37/222; H01J 37/265; H01J 37/28; H01J 2237/2817

(57) ABSTRACT

Provided is a correction method capable of reducing defocus in an image caused by variations in height of a semiconductor pattern by image processing performed after imaging. This correction method for correcting an image includes: acquiring a target image 801 in which a semiconductor pattern having a plurality of areas the height of which varies step-wisely is imaged; storing a plurality of correction coefficients C1 and the like for correcting the respective areas of the acquired target image 801; and correcting the respective areas of the target image 801 using the stored plurality of correction coefficients C1 and the like.

### TECHNICAL FIELD

The present disclosure relates to a correction method and a correction device for correcting a target image obtained by imaging a semiconductor pattern.

### BACKGROUND ART

Charged particle beam devices such as scanning electron microscopes (SEMs) are devices appropriate for measuring or observing semiconductor patterns formed on increasingly miniaturized semiconductor wafers. Electron beam observation devices such as scanning electron microscopes accelerate electrons from electron sources and converge the electrons to a sample surface by an electrostatic lens or an electronic lens for irradiation. The irradiated electrons are called primary electrons. Secondary electrons (in some cases, electrons with low energy are referred to as secondary electrons and electrons with high energy are referred to as backscattered electrons) are emitted from samples by incidence of the primary electrons. By detecting the secondary electrons while deflecting and scanning electron beams, it is possible to obtain scanned images with minute patterns or composition distributions on the samples. To obtain scanned images with high resolutions, focusing is performed by controlling electrostatic lenses or electronic lenses according to heights of samples or charging states of sample surfaces so that diameters of electron beams emitted to patterns are minimized. In general, a method of capturing a plurality of images while changing a focus position and selecting the focus position at which sharpness of the image is maximized is known. However, when electron beams are irradiated to observation target positions for focusing, wear of target areas due to electron beams becomes a problem. When focusing is performed on each observation target at each time, a throughput deteriorates.

PTL 1 proposes a method of setting an adjustment area around a target area and determining an optical condition of the target area based on an optical condition of an optical system in the adjustment area. PTL 2 discloses a method of generating a height map by measuring and storing a height of a sample in advance by a height sensor, and shortening a focusing time by comparing with the height map during imaging.

### CITATION LIST

### Patent Literature

PTL 1: JP2019-160464A

PTL 2: JP2009-259878A

### SUMMARY OF INVENTION

### Technical Problem

PTL 1 and PTL 2 do not clearly disclose a focusing method that targets a semiconductor pattern of which a height varies step-wisely. During imaging of the semiconductor pattern of which the height varies step-wisely, when a certain height is in focus, patterns at other heights are not in focus, and thus defocus occurs in a captured image.

To solve the defocus, a method of capturing a plurality of images focusing on each height of a semiconductor pattern and combining the images at a later stage can be considered. However, there is concern of an influence of damage or charging on an imaging target since irradiation areas overlap for combination. A throughput may deteriorate due to the capturing and combination of the plurality of images.

The present disclosure provides a technique capable of reducing defocus in an image caused by variations in height of a semiconductor pattern by image processing performed after imaging.

### Solution to Problem

To solve the foregoing problem, according to an aspect of the present invention, a correction method includes: acquiring a target image in which a semiconductor pattern having a plurality of areas the height of which varies step-wisely is imaged; storing a plurality of image correction values for correcting the respective areas of the target image; and correcting the respective areas of the target image using the stored plurality of image correction values.

### Advantageous Effects of Invention

According to the present disclosure, it is possible to reduce defocus in an image caused by variations in height of a semiconductor pattern by image processing performed after imaging.

Other tasks, configurations, and effects will be apparent from description of the following embodiments.

### BRIEF DESCRIPTION OF DRAWINGS

FIG. 1 is a diagram illustrating an overall configuration of a scanning electron microscope according to Example 1.

FIG. 2 is a diagram illustrating a sectional view of a semiconductor pattern and an image of the semiconductor pattern.

FIG. 3 is a flowchart illustrating a procedure for calculating a correction coefficient.

FIG. 4 is a diagram illustrating a window function.

FIG. 5 is a diagram illustrating a procedure for calculating a correction coefficient.

FIG. 6 is a diagram illustrating a procedure for calculating a correction coefficient.

FIG. 7 is a flowchart illustrating a procedure for correcting an image by applying the calculated correction coefficient.

FIG. 8 is a diagram illustrating a procedure for correcting an image by applying the calculated correction coefficient.

FIG. 9 is a diagram illustrating an example of an environment setting screen displayed on a display device in the procedure for calculating a correction coefficient.

FIG. 10 is a diagram illustrating an example of an environment setting screen displayed on the display device in the procedure for correcting an image.

FIG. 11 is a flowchart illustrating a procedure for calculating a correction coefficient according to Example 2.

FIG. 12 is a flowchart illustrating a procedure for correcting an image by applying a correction coefficient calculated by another device according to Example 3.

### DESCRIPTION OF EMBODIMENTS

Embodiments of the present disclosure will be described in detail with reference to the drawings. In the following embodiments, it is needless to say that components (including elements and steps) may not be necessarily essential unless otherwise specified and deemed essential in principle.

Hereinafter, examples appropriate for the present disclosure will be described with reference to the drawings. In the examples, a scanning electron microscope will be described as an example, but the present disclosure can also be applied to electron beam observation devices other than scanning electron microscopes.

### Example 1

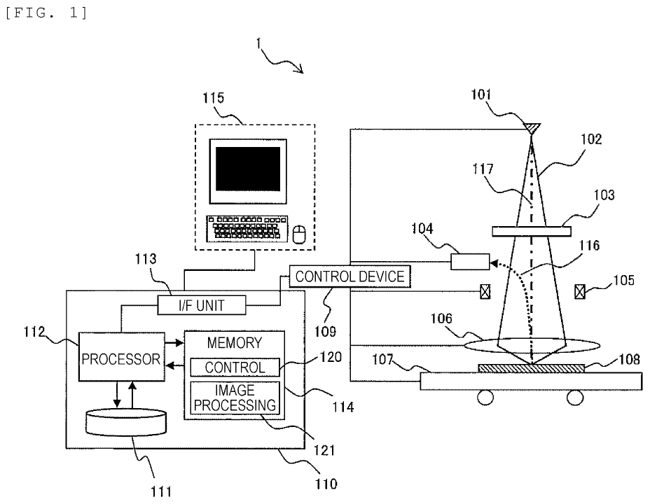

FIG. 1 is a diagram illustrating an overall configuration of a scanning electron microscope according to Example 1. A configuration of the scanning electron microscope will be described with reference to FIG. 1.

### <Scanning Electron Microscope 1>

The scanning electron microscope 1 includes an electron source 101, a deformation illumination diaphragm 103, a detector 104, a scanning deflection deflector 105, an objective lens 106, a stage 107, a control device 109, a system control unit 110, and an input/output unit 115.

In a downstream direction in which an electron beam 102 is output from the electron source 101, the deformation illumination diaphragm 103, the detector 104, the scanning deflection deflector 105, and the objective lens 106 are disposed. An electronic optical system includes an aligner (not illustrated) and an aberration corrector (not illustrated) that adjust a central axis (optic axis) 117 of a primary beam. The objective lens 106 according to Example 1 is an electronic lens that controls focusing by an excitation current, but may be an electrostatic lens or a composite lens of an electronic lens and an electrostatic lens. The stage 107 is configured to move while a sample 108 (for example, a semiconductor wafer) is placed thereon. The control device 109 is connected to each unit of the electron source 101, the detector 104, the scanning deflection deflector 105, the objective lens 106, and the stage 107 to be communicable. The system control unit 110 is connected to the control device 109 to be communicable.

In the present example, the detector 104 is disposed upstream of the objective lens 106 or the scanning deflection deflector 105, but the disposition order is not limited to the disposition of FIG. 1. The aligner (not illustrated) that corrects the optic axis 117 of the electron beam 102 is disposed between the electron source 101 and the objective lens 106. The aligner corrects a central axis of the electron beam 102 when the central axis of the electron beam 102 deviates from a diaphragm or an electronic optical system.

The electron beam 102 output from the electron source 101 converges so that a beam diameter is minimized on the sample 108 by adjusting focus with the objective lens 106. The scanning deflection deflector 105 is controlled by the control device 109 so that the electron beam 102 scans a fixed area of the sample 108. The electron beam 102 arriving at the surface of the sample 108 interacts with a material near the surface. Accordingly, secondary electrons such as backscattered electrons, secondary electrons, or Auger electrons are generated from the sample 108. In the present example, an electronic microscope image is displayed using a signal of secondary electrons 116. The secondary electrons 116 generated from a position at which the electron beam 102 arrives at the sample 108 are detected by the detector 104. Signal processing on the secondary electrons 116 detected by the detector 104 is performed in synchronization with a scanning signal sent from the control device 109 to the scanning deflection deflector 105 to form an SEM image. Accordingly, the sample 108 can be observed.

It is needless to say that components other than a control system and a circuit system is disposed within a vacuum container and operate within the evacuated vacuum container. The scanning electron microscope 1 includes a wafer transport system that places the sample 108 such as a semiconductor wafer from outside the vacuum on the stage 107.

### <System Control Unit 110>

The system control unit 110 is a correction device that corrects a target image obtained by imaging a semiconductor pattern that has a plurality of areas of which heights vary step-wisely. The correction device may be on-premises or in a cloud. The system control unit 110 includes a storage device 111, a processor 112, an input/output interface unit (hereinafter abbreviated to an I/F unit) 113, and a memory 114. An input/output unit 115 including an output device such as a display device and an input device such as a keyboard or a mouse is connected to the I/F unit 113 to be communicable. The input/output unit 115 may be a touch panel in which an input device and an output device are integrated.

The processor 112 is, for example, a central processing unit (CPU), a digital signal processor (DSP), an application specific integrated circuit (ASIC), or the like. The processor 112 loads a program stored in the storage device 111 in a working area of the memory 114 so that the program can be executed. The memory 114 stores a program that is executed by the processor 112, data that is processed by the processor, and the like. The memory 114 is a flash memory, a random access memory (RAM), a read only memory (ROM), or the like. The storage device 111 stores various programs and various data. The storage device 111 stores, for example, an operating system (OS), various programs, various tables, and the like. The storage device 111 is a silicon disc including a nonvolatile semiconductor memory (a flash memory or an erasable programmable ROM (EPROM)), a solid-state drive device, a hard disk drive (HDD) device, or the like.

The processor 112 loads a control program 120, an image processing program 121, or the like stored in the storage device 111 in the memory 114 so that the programs can be executed. The processor 112 executes the control program 120 or the image processing program 121 to perform image processing related to defect inspection or numerical value measurement of a semiconductor ware, control of the control device 109, or the like. The storage device 111 stores a plurality of image correction values for correcting each area of which a height of a target image is different. The image correction values are, for example, correction coefficients to be described below. The image correction value may be a table, a function, a mathematical formula, a mathematical model, a trained learning model, or a DB. The image processing program 121 is a program that processes an SEM image.

### <Control Device 109>

The control device 109 includes a storage device, a processor, an I/F unit, and a memory as in the system control unit 110. The storage device (not illustrated) of the control device 109 stores a program that moves the stage 107, a program that controls focus of the objective lens 106, and the like. The processor (not illustrated) of the control device 109 loads and executes a program stored in the storage device in the memory (not illustrated). The I/F unit (not illustrated) of the control device 109 is connected to the system control unit 110, the electron source 101, the deformation illumination diaphragm 103, the detector 104, the scanning deflection deflector 105, the objective lens 106, and the stage 107 to be communicable.

### <Method of Correcting Microscope Image>

Hereinafter, a method of correcting a microscope image (image) obtained by imaging a semiconductor pattern that has a plurality of areas of which heights vary step-wisely will be described. Since the height of the semiconductor pattern is different depending on a position, the semiconductor pattern is not in focus at all the positions in an image. Accordingly, a correction method and a device for correcting an image will be described using an image correction value determined in advance for each area of which the height is different.

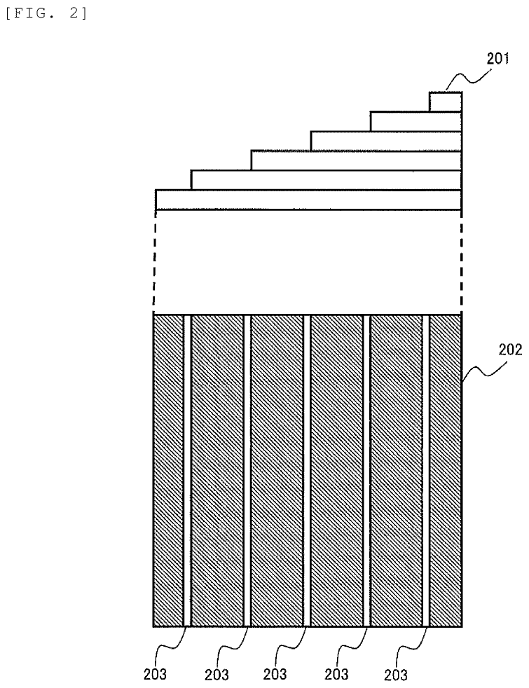

FIG. 2 is a diagram illustrating a sectional view of a semiconductor pattern and an image of the semiconductor pattern. A semiconductor pattern 201 illustrated in FIG. 2 has a plurality of areas of which heights vary step-wisely. An image 202 illustrated in FIG. 2 is an image obtained by imaging the semiconductor pattern 201 in FIG. 2 by scanning an electron beam from the top direction of the drawing. When the electron beam is irradiated to a portion in which the height of the semiconductor pattern 201 varies step-wisely, many secondary electrons are generated in edge portions of the semiconductor pattern 201. Therefore, white bands 203 brighter than that of other areas are illustrated in the image 202. When an area with any height of the semiconductor pattern 201 is in focus, other areas of which heights are different are not in focus and defocus occurs in the image 202. That is, when one white band is in focus in the image 202, other white bands of which the heights are different are in defocus.

Accordingly, in the image 202 of Example 1, each area of which the height is different is corrected through image processing SO that area every has the same frequency characteristic as the case of being in focus. The correction method according to Example 1 is broadly divided into a procedure for calculating a correction coefficient and a procedure for correcting an image by applying the calculated correction coefficient.

### <Procedure for Calculating Correction Coefficient>

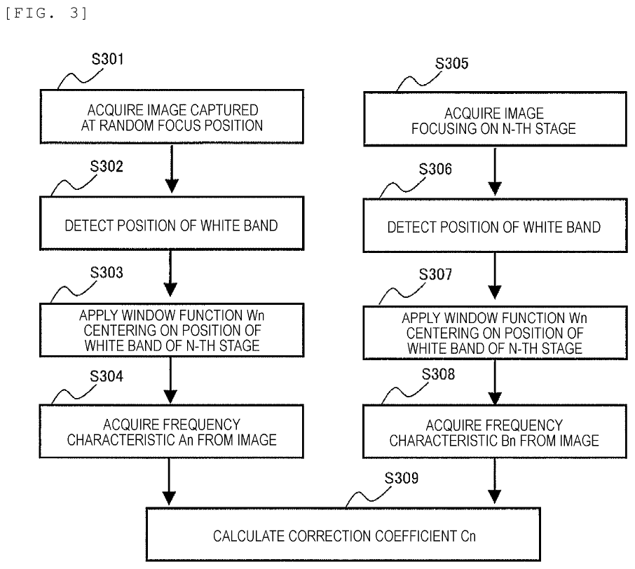

First, a procedure for calculating a correction coefficient will be described with reference to the flowchart of FIG. 3. When an image with a semiconductor pattern that has a plurality of areas of which heights vary step-wisely (target image) is corrected, a correction coefficient is calculated for each area of which the height is different. Each step of FIG. 3 is performed by the system control unit 110 that is a computer system.

A procedure for calculating a correction coefficient used to correct an N-th (N is a random integer) stage image of a semiconductor pattern that has areas of which heights are different will be described with reference to FIG. 3. First, a reference semiconductor pattern is imaged at a random focus position and the system control unit 110 acquires one or more images (reference images) (S301). In the procedure for correcting an image by applying the calculated correction coefficient to be described below, the semiconductor pattern is imaged at the same position as the random focus position.

Subsequently, the system control unit 110 detects a position of the white band of the image acquired in S301 (S302). As the detection of the position of the white band, a method of acquiring a luminance profile of the image, detecting a peak position of the profile, and setting an N-th peak position as a position of a white band of an N-th stage is considered. The method of detecting the position of the white band is not limited thereto. In the present example, an example in which the position of the white band is detected as the position of the semiconductor pattern will be described. However, the position of the semiconductor pattern is not limited to the position of the white band as long as the position of the semiconductor pattern such as a position of an edge, a contour line, or the like of the semiconductor pattern can be detected.

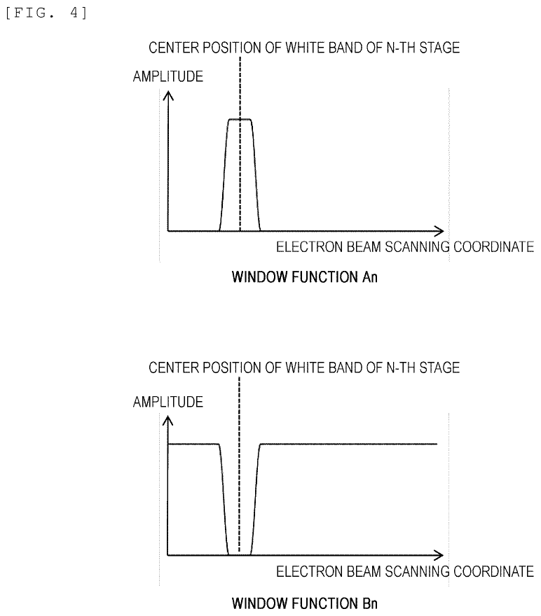

Subsequently, the system control unit 110 applies a window function Wn centering on the position of the white band of the N-th stage (S303). Here, the window function Wn will be described with reference to FIG. 4. In Example 1, a Tukey window is used as an example of the window function, but the window function may be another window function such as a rectangular window or a Gauss window. The window function Wn in FIG. 4 is a function that returns 0 in areas other than an area centering on the position of the white band of the N-th stage. An amplitude of the function is assumed to be normalized in a range of 0 to 1. By applying the window function Wn to an image, it is possible to generate an image from which an area centering on the position of the white band of the N-th stage is extracted.

Subsequently, the system control unit 110 performs Fourier transform or the like on the image extracted by the window function Wn to transform the image into an image of a frequency space and acquires a frequency characteristic (reference frequency characteristic) An from the image (S304).

The system control unit 110 changes a focus position and performs processes of S305 to S308 as in S301 to S304. Specifically, the system control unit 110 images the reference semiconductor pattern focusing on the N-th stage and acquires one or more images (focusing images) (S305). Subsequently, the system control unit 110 detects a position of the white band of the image acquired in S305 (S306). Subsequently, the system control unit 110 applies the window function Wn centering on the position of the white band of the N-th stage to the image captured in focus on the N-th stage (S307). Subsequently, the system control unit 110 performs Fourier transform or the like on the image extracted by the window function Wn to transform the image to an image of a frequency space and acquires a frequency characteristic Bn from the image (S308).

A correction coefficient Cn for correcting the image centering on the position of the white band of the N-th stage is calculated by the following formula (S309).

Correction coefficient Cn=Frequency characteristic Bn/Frequency characteristic An (Formula 1)

The correction coefficient Cn is calculated for each pixel of the image obtained by transforming an image to a frequency space. The correction coefficient Cn is calculated for each of the plurality of areas of which the heights are different.

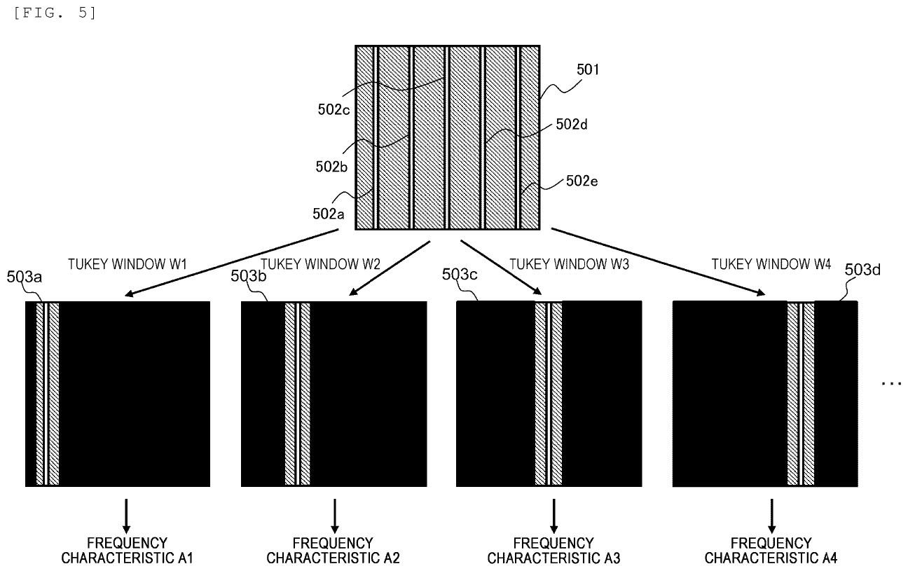

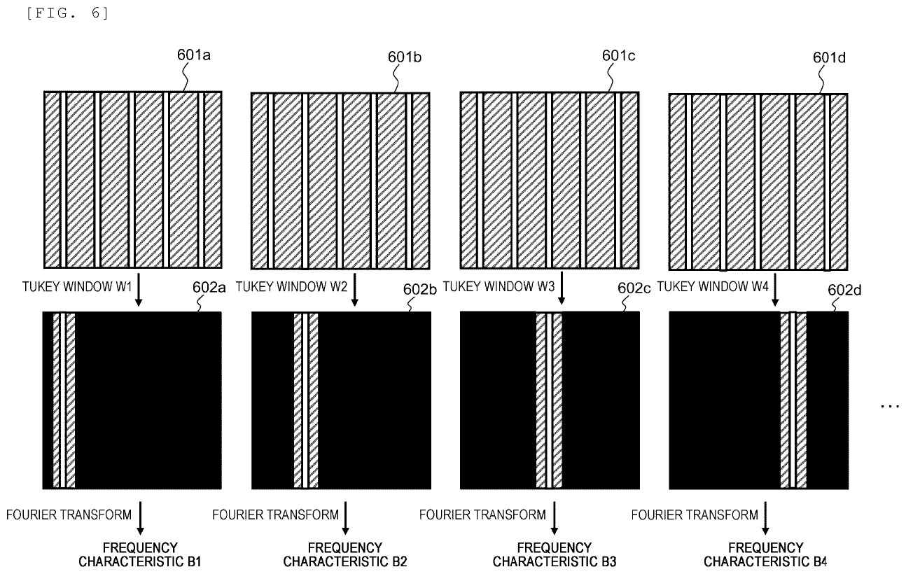

Next, a method of calculating a plurality of correction coefficients for each of the plurality of areas of which the heights are different will be described with reference to FIGS. 5 and 6. Here, a method of calculating four correction coefficients C1 to C4 for each of four areas will be described. It is needless to say that the number of areas is not limited to four. First, the scanning electron microscope 1 images the reference semiconductor pattern at a random focus position and acquires one or more images (reference images) 501. The system control unit 110 detects positions of white bands 502a to 502e of the acquired image 501. Then, the system control unit 110 applies each of Tukey windows W1 to W4 centering on the positions of the white bands 502a to 502d to the image 501 and acquires the images 503a to 503d.

The system control unit 110 performs Fourier transform or the like on the images 503a to 503d to transform the images to images of a frequency space and acquires frequency characteristics (reference frequency characteristics) A1 to A4 from the images.

Subsequently, as illustrated in FIG. 6, the scanning electron microscope 1 images the reference semiconductor pattern in focus on positions of first to fourth stages and acquires the images (focusing images) 601a to 601d. Subsequently, the system control unit 110 detects the positions of the white bands of the images 601a to 601d. Then, the system control unit 110 applies the window functions (Tukey windows) W1 to W4 centering on the positions of the white bands of the first to fourth stages to the images 601a to 601d.

Subsequently, the system control unit 110 performs Fourier transform or the like on the images 602a to 602d extracted by the window functions (Tukey windows) W1 to W4 to transform the images into images of a frequency space and acquires frequency characteristics B1 to B4 from the images.

Then, the system control unit 110 calculates correction coefficients C1=B1/A1, C2=B2/A2, C3=B3/A3, and C4=B4/A4 based on the foregoing (Formula 1).

<Procedure for Correcting Image by Applying Calculated Correction Coefficient>

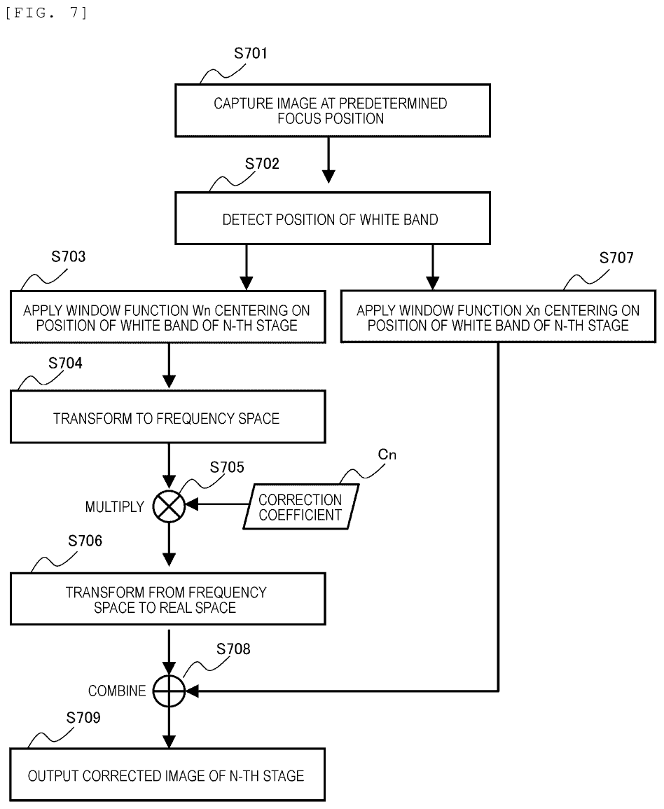

Next, a procedure for correcting an image by applying the calculated correction coefficient will be described with reference to the flowchart of FIG. 7. Each step of FIG. 7 is performed by the system control unit 110 that is a computer system. A procedure for correcting an N-th (N is a random integer) stage image of a semiconductor pattern that has areas of which heights are different will be described with reference to FIG. 7. The correction performed in the procedure is correction related to focus adjustment of a microscope that captures a target image.

A target (semiconductor pattern) is imaged at a predetermined focus position and the system control unit 110 acquires one or more images (target images) (S701). The predetermined focus position is the same focus position as a position when the image is acquired in S301 of FIG. 3. Subsequently, the system control unit 110 detects a position of the white band of the image acquired in S701 (S702). Subsequently, the system control unit 110 applies the window function Wn centering on a position of the white band of the N-th stage (S703). By applying the window function Wn to an image, it is possible to generate an image from which an area centering on the position of the white band of the N-th stage is extracted.

Subsequently, the system control unit 110 performs Fourier transform or the like on the image extracted by the window function Wn to transform the image into an image of a frequency space (S704). Then, the system control unit 110 multiplies each pixel of the image of the frequency space by the correction coefficient Cn (=frequency characteristic Bn/frequency characteristic An) calculated in the procedure for calculating the correction coefficient (S705). Subsequently, the system control unit 110 transforms the image of the frequency space multiplied by the correction coefficient Cn into an image of a real space according to a scheme such as a two-dimensional inverse Fourier transform (S706).

The system control unit 110 applies a window function Xn to the image acquired in S701 (S707). The window function Xn is calculated by the following formula.

Window function Xn=1.0−Window function Wn (Formula 2)

Here, the window function Xn will be described with reference to FIG. 4. The window function Xn of FIG. 4 is a function that returns 0 in an area centering on the position of the white band of the N-th stage. An amplitude of the function is assumed to be normalized in a range of 0 to 1. By applying the window function Xn to an image, it is possible to generate an image from which areas other than the area centering on the position of the white band of the N-th stage is extracted.

The system control unit 110 combines the image acquired in S706 with the image acquired in S707 (S708). Combination means summing each pixel of two images. The corrected image of the N-th stage is output through the combination of the two images (S709). The corrected image is an image in which only the area centering on the position of the white band of the N-th stage is corrected. Therefore, when correction of a plurality of stages is performed, each process of the flowchart of FIG. 7 described above needs to be performed a plurality of times.

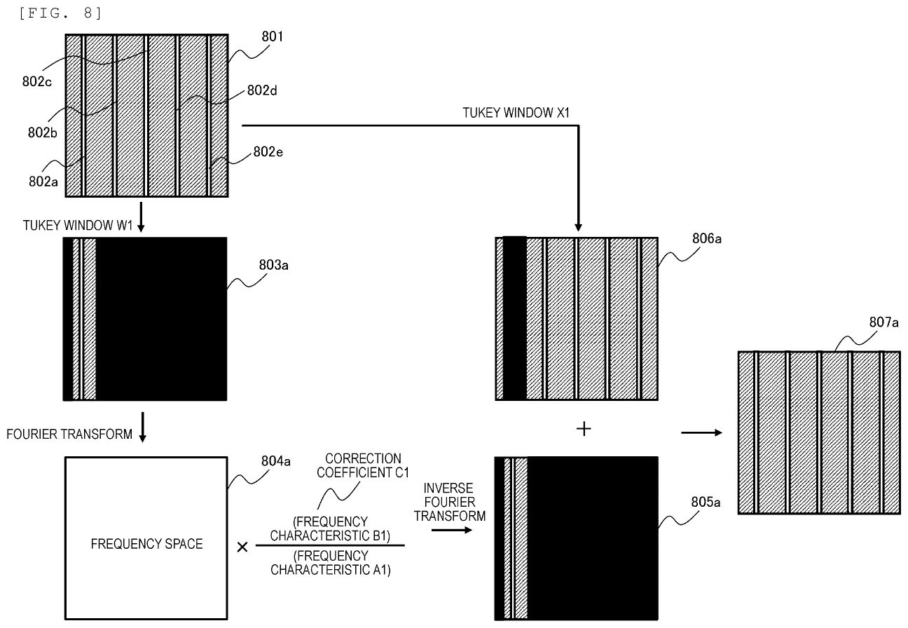

Next, a method of outputting a combined image will be described with reference to FIG. 8. Here, a method of correcting an image of a first stage will be described. First, the scanning electron microscope 1 images a target (semiconductor pattern) at a predetermined focus position and acquires one or more images (target image) 801. The system control unit 110 detects positions of white bands 802a to 802e of the acquired image 801. The system control unit 110 applies the window function (Tukey window) W1 centering on the position of the white band 802a to the image 801 and acquires an image 803a.

The system control unit 110 performs Fourier transform or the like on the image 803a to transform the image into an image 804a of a frequency space. Then, the system control unit 110 multiplies each pixel of the image 804a of the frequency space by the correction coefficient C1 (=frequency characteristic B1/frequency characteristic A1). Subsequently, the system control unit 110 transforms the image 804a of the frequency space multiplied by the correction coefficient C1 into an image 805a of the real space according to a scheme such as a two-dimensional inverse Fourier transform.

The system control unit 110 acquires an image 806a by applying a window function (Tukey window) X1 to the image 801. Then, the image 805a and the image 806a of the real space are combined to acquire a corrected image 807a.

### <Graphical User Interface (GUI)>

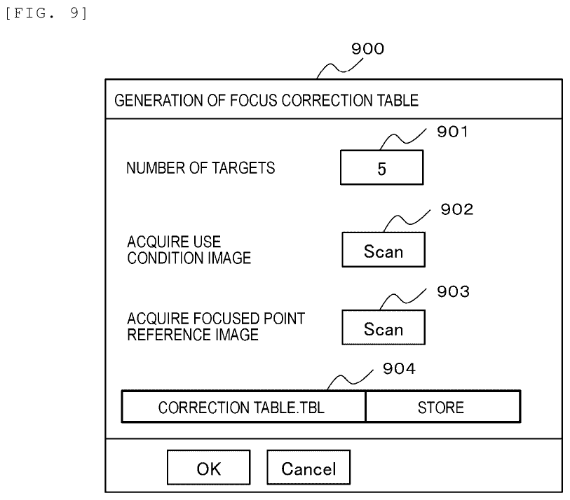

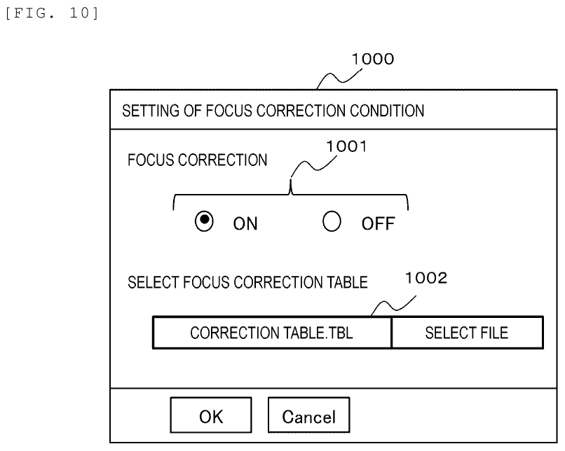

FIGS. 9 and 10 illustrate examples of graphical user interfaces (GUIs) on which environment setting according to Example 1 is performed. FIG. 9 is a diagram illustrating an example of an environment setting screen 900 displayed on a display device of the input/output unit 115 in the procedure for calculating a correction coefficient.

The environment setting screen 900 includes a text box 901 for inputting the number of areas of which heights are different, a button 902 for capturing an image at a random focus position, and a button 903 for imaging a reference semiconductor pattern while changing a focus position by the number input in the text box 901. The environment setting screen 900 includes a file storage portion 904 in which the calculated correction coefficient is stored as a file with any name.

FIG. 10 is a diagram illustrating an example of an environment setting screen 1000 output on the display device of the input/output unit 115 in the procedure for correcting an image by applying the calculated correction coefficient. The environment setting screen 1000 includes a switch 1001 for setting whether to correct the captured image to ON or OFF in the drawing and a file selection portion 1002 for selecting a file in which the correction coefficient is stored. In the file selection portion 1002, a file stored in the file storage portion 904 can be selected.

### Advantageous Effects of Example 1

In Example 1, the plurality of correction coefficients C1 to Cn for correcting each of the plurality of areas of the image (target image) 801 are stored. Accordingly, defocus of the image (target image) 801 caused by variations in height of the semiconductor pattern can be reduced through image processing after imaging.

In Example 1, each area of the image (target image) 801 can be corrected with each of the plurality of correction coefficients. Therefore, the image (target image) 801 is captured only once. Accordingly, since it is not necessary to irradiate the electron beam to the semiconductor pattern repeatedly, an influence of damage or charging on the semiconductor pattern can be reduced.

As described above, the semiconductor pattern is imaged only once. Therefore, a throughput is improved compared to a case in which imaging is performed repeatedly according to the height of the semiconductor pattern.

In Example 1, since the correction of each area of the image (the target image) 801 is correction related to focus adjustment of the scanning electron microscope 1, defocus can be reduced through image processing after imaging.

In Example 1, the plurality of correction coefficients C1 to Cn can be calculated for each focus position based on the image (reference image) 501 and a plurality of images (focusing images) 601a to 601n which are captured while changing a focus position. Accordingly, since each area of the image (target image) 801 can be corrected with the correction coefficients C1 to Cn appropriate for each area, an image of which defocus is reduced can be obtained.

In Example 1, by calculating frequency characteristics of the image (reference image) 501 or the images (focusing images) 601a to 601n through Fourier transform, it is possible to easily obtain the plurality of correction coefficients for correcting each area of the image (target image) 801.

In Example 1, since the image 805a of the real space can be obtained through inverse Fourier transform, an observer can observe the image 805a of the real space of the semiconductor pattern.

In Example 1, it is possible to calculate the correction coefficients C1 to Cn for reducing defocus of each of the areas centering on the white bands by using the white bands 502a to 502e of the image (reference image) 501, the white bands of the images (focusing images) 601a to 601n, and the window functions W1 to Wn that extract the areas centering the white bands.

In Example 1, each of the plurality of areas of the image (target image) 801 can be individually corrected using the correction coefficients C1 to Cn.

In Example 1, the number of areas of which the heights are different can be input in the environment setting screen 900. Accordingly, each area of the image (target image) 801 can be corrected with a number designated by the user.

### Example 2

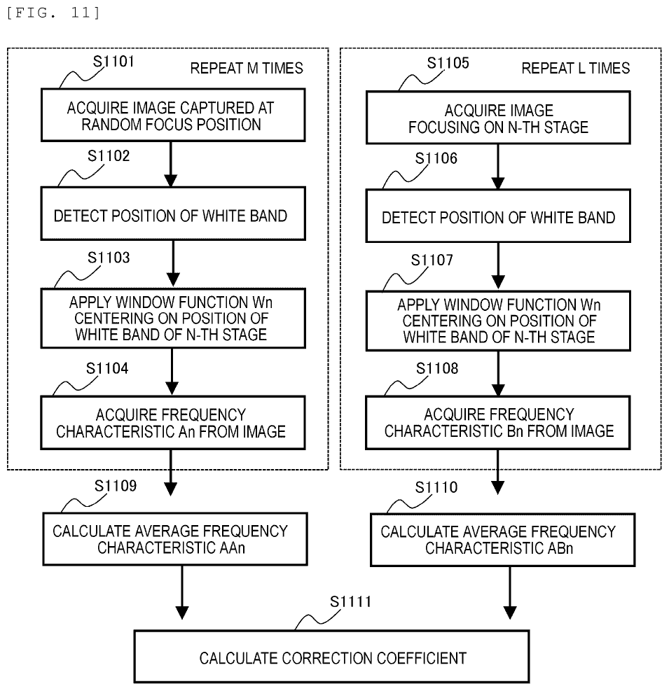

The frequency characteristics for calculating the correction coefficients can also be acquired from one image. However, to reduce an influence of variation in value due to noise or the like, frequency characteristics may be calculated from a plurality of images captured under the same condition. For example, frequency characteristics of a plurality of images captured under the same condition may be averaged and correction coefficients may be calculated using the average value. In Example 2, an example in which correction coefficients are calculated from an average of frequencies of a plurality of images captured under the same condition will be described with reference to FIG. 11. Each step of FIG. 11 is performed by the system control unit 110 that is a computer system.

As illustrated in FIG. 11, the system control unit 110 repeats processes of S1101 to S1104 M times. The processes of S1101 to S1104 are the same as the processes of S301 to S304 of FIG. 3, and thus description thereof will be omitted. Then, the system control unit 110 averages M frequency characteristics An to acquire an average frequency characteristic AAn (S1109).

The system control unit 110 repeats processes of S1105 to S1108 L times. The processes of S1105 to S1108 are the same as the processes of S305 to S308 of FIG. 3, and thus description thereof will be omitted. The system control unit 110 averages L frequency characteristics Bn to acquire an average frequency characteristic ABn (S1110).

A correction coefficient ACn for correcting an image centering on a position of a white band of an N-th stage is calculated by the following formula (S1111).

Correction coefficient ACn=Frequency characteristic ABn/Frequency characteristic AAn (Formula 3)

The correction coefficient is calculated for each pixel of an image obtained by transforming an image to a frequency space.

Each of the foregoing M and L is an integer of 1 or more. M and L may be different values or may be the same value. An average of the frequency characteristics means an average of amplitude characteristics at each frequency.

### Advantageous Effects of Example 2

In Example 2, even when noise or variation occurs during capturing of the image (reference image) 501 or during capturing of the images (focusing images) 601a to 601d, an influence of noise or variation can be reduced by using the average of the frequency characteristics. Since other advantageous effects are similar to those of Example 1, description thereof will be omitted.

### Example 3

In Example 1, the example in which the procedure for calculating the correction coefficients and the procedure for correcting the image by applying the calculated correction coefficients are performed by one device has been described. In Example 3, an example in which a plurality of devices are operated and the correction coefficients acquired by a certain device are applied to an image captured by another device will be described.

The procedure for calculating the correction coefficients is similar to FIG. 3 or 11, and thus will be omitted. Since the procedure for correcting the image by applying the calculated correction coefficients is performed by each device similarly to that of FIG. 7, description thereof will be omitted. When the number of areas of which heights are different is N, N correction coefficients are acquired and correction of an image is applied separately N times, but description thereof will be omitted in FIG. 11. An electron beam observation device (hereinafter, an “electron beam observation device” is referred to as a “device”) A transforms an image IA captured by the device A to a frequency space (S1201), multiplies the image of the frequency space by a correction coefficient CA calculated by the device A (S1202), and transforms the image into an image of the real space (S1203). Accordingly, a correction result image CIA is acquired. On the other hand, a device B transforms an image IB captured by the device B to the frequency space (S1204), multiplies the image of the frequency space by the correction coefficient CA calculated by the device A (S1205), and transforms the image into an image of the real space (S1206). Accordingly, a correction result image CIB is acquired.

### Advantageous Effects of Example 3

By using the correction coefficient CA calculated by the device A for the image captured by the device B, the correction result image CIB becomes closer to a frequency characteristic of an image captured by the device A. That is, the correction result image CIB is close to the image captured by the device A and instrumental error between the devices A and B can be reduced. Since other advantageous effects are similar to those of Examples 1 and 2, description thereof will be omitted.

The present disclosure is not limited to the foregoing examples and includes various modified examples. The foregoing examples have been described in detail to describe the present disclosure to be easily understood and the present disclosure is not limited to embodiments in which all of the described configurations are included. Some of the configurations of a certain embodiment can be replaced with configurations of another embodiment, and the configurations of another embodiment can also be added to configurations of a certain embodiment. Other configurations can be added to, deleted from, or replaced by some of the configurations of each example.

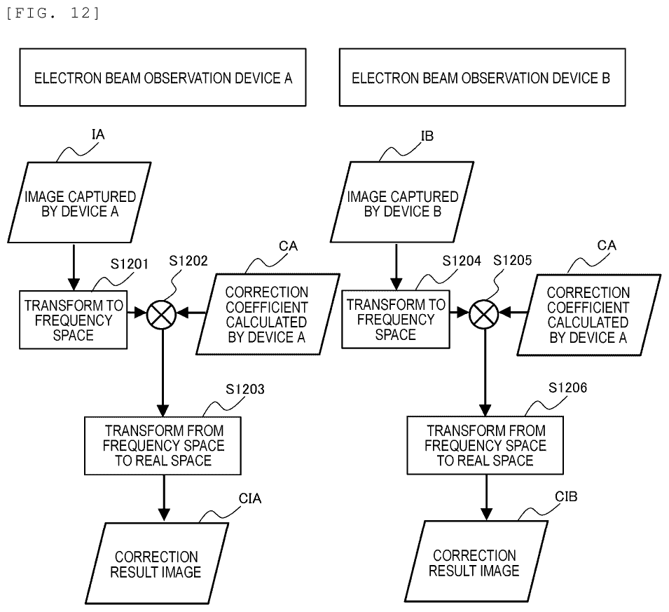

In Examples 1 to 3, the examples in which the system control unit 110 performs each step of FIGS. 3, 7, 11, and 12 have been described, but the control device 109 may perform each of the above-described steps. The system control unit 110 and the control device 109 may share and perform each of the above-described steps.

### REFERENCE SIGNS LIST

1: scanning electron microscope
101: electron source
102: electron beam
103: deformation illumination diaphragm
104: detector
105: scanning deflection deflector
106: objective lens
107: stage
108: sample
109: control device
110: system control unit
111: storage device
112: processor
113: input/output interface unit
114: memory
115: input/output unit
116: secondary electron
117: optic axis
120: control program
121: image processing program
201: semiconductor pattern
202: image
501: reference image
502a to 502e: white band
503a to 503d: image to which window function is applied
601a to 601d: focusing image
602a to 602d: image to which window function is applied
801: image obtained by imaging target at predetermined focus position
802a to 802e: white band
803a: image to which window function is applied
804a: image of frequency space
805a: image of real space
806a: image to which window function is applied
807a: corrected image
900: environment setting screen
901: text box
902: button
903: button
904: file storage portion
1000: environment setting screen
1001: switch
1002: file selection portion

1. A correction method comprising:
acquiring a target image obtained by imaging a semiconductor pattern that has a plurality of areas of which heights vary step-wisely;
storing a plurality of image correction values for correcting each area of the target image; and
correcting each area of the target image using the stored plurality of image correction values.

2. The correction method according to claim 1, wherein the correction of each area of the target image is correction related to focus adjustment of a microscope that captures the target image.

3. The correction method according to claim 1, further comprising:
acquiring a reference image obtained by imaging a reference semiconductor pattern at a random focus position; and
acquiring a first focusing image obtained by imaging the reference semiconductor pattern in focus at a first position and acquiring a second focusing image obtained by imaging the reference semiconductor pattern in focus at a second position different from the first position, wherein
the plurality of image correction values include a first correction coefficient calculated based on the reference image and the first focusing image and a second correction coefficient calculated based on the reference image and the second focusing image.

4. The correction method according to claim 3, further comprising:
acquiring a reference frequency characteristic by performing Fourier transform on the reference image; and
acquiring first and second frequency characteristics by performing Fourier transform on each of the first and second focusing images, wherein
the first correction coefficient is a correction coefficient calculated based on the reference frequency characteristic and the first frequency characteristic, and the second correction coefficient is a correction coefficient calculated based on the reference frequency characteristic and the second frequency characteristic.

5. The correction method according to claim 4, further comprising:
acquiring an image of a frequency space by performing Fourier transform on the target image;
applying the first or second correction coefficient to each area of the image of the frequency space; and
acquiring an image of a real space by performing inverse Fourier transform on each of a first image of the frequency space to which the first correction coefficient is applied and a second image of the frequency space to which the second correction efficient is applied.

6. The correction method according to claim 3, further comprising:
detecting positions of first and second patterns of the reference image;
applying a first window function to an area including the position of the first pattern of the reference image and applying a second window function to an area including the position of the second pattern of the reference image;
acquiring a first focusing image obtained by imaging the reference semiconductor pattern in focus on an area corresponding to the position of the first pattern and acquiring a second focusing image obtained by imaging the reference semiconductor pattern in focus on an area corresponding to the position of the second pattern;
detecting a position of a pattern of the first focusing image and detecting a position of a pattern of the second focusing image; and
applying the first window function to an area including a position of a pattern corresponding to the first pattern of the first focusing image and applying the second window function to an area including a position of a pattern corresponding to the second pattern of the second focusing image, wherein
the image correction values include a first correction coefficient calculated based on the reference image to which the first window function is applied and the first focusing image to which the first window function is applied, and a second correction coefficient calculated based on the reference image to which the second window function is applied and the second focusing image to which the second window function is applied.

7. The correction method according to claim 6, further comprising:
detecting a position of a third pattern corresponding to the first pattern of the target image and detecting a fourth pattern corresponding to the second pattern of the target image; and
applying the first window function to an area including a position of the third pattern of the target image and applying the second window function to an area including a position of the fourth pattern of the target image, wherein
the correction includes correcting the target image to which the first window function is applied using the first correction coefficient and correcting the target image to which the second window function is applied using the second correction coefficient.

8. The correction method according to claim 1, further comprising displaying an environment setting screen for designating the number of the plurality of image correction values.

9. The correction method according to claim 1, further comprising:
acquiring a plurality of reference images obtained by imaging a reference semiconductor pattern at random focus positions a plurality of times; and
acquiring a plurality of first focusing images obtained by imaging the reference semiconductor pattern in focus on a first position a plurality of times and acquiring a plurality of second focusing images obtained by imaging the reference semiconductor pattern in focus on a second position different from the first position a plurality of times, wherein
the plurality of image correction values include a first correction coefficient calculated based on the plurality of reference images and the plurality of first focusing images and a second correction coefficient calculated based on the plurality of reference images and the plurality of second focusing images.

10. The correction method according to claim 3, wherein the plurality of image correction values are image correction values calculated based on an image of the reference semiconductor pattern captured by a device different from a device capturing the target image.

11. A correction device comprising a computer system that includes a processor and a memory, wherein
the computer system
acquires a target image obtained by imaging a semiconductor pattern that has a plurality of areas of which heights vary step-wisely,
stores a plurality of image correction values for correcting each area of the target image, and
corrects each area of the target image using the stored plurality of image correction values.

12. The correction device according to claim 11, wherein the correction of each area of the target image is correction related to focus adjustment of a microscope that captures the target image.

13. The correction device according to claim 11, wherein
the computer system
acquires a reference image obtained by imaging a reference semiconductor pattern at a random focus position, and
acquires a first focusing image obtained by imaging the reference semiconductor pattern in focus at a first position and acquires a second focusing image obtained by imaging the reference semiconductor pattern in focus at a second position different from the first position, and
the plurality of image correction values include a first correction coefficient calculated based on the reference image and the first focusing image and a second correction coefficient calculated based on the reference image and the second focusing image.

14. The correction device according to claim 13, wherein
the computer system
acquires a reference frequency characteristic by performing Fourier transform on the reference image, and
acquires first and second frequency characteristics by performing Fourier transform on each of the first and second focusing images, and
the first correction coefficient is a correction coefficient calculated based on the reference frequency characteristic and the first frequency characteristic, and the second correction coefficient is a correction coefficient calculated based on the reference frequency characteristic and the second frequency characteristic.

15. The correction device according to claim 14, wherein
the computer system
acquires an image of a frequency space by performing Fourier transform on the target image,
applies the first or second correction coefficient to each area of the image of the frequency space, and
acquires an image of a real space by performing inverse Fourier transform on each of a first image of the frequency space to which the first correction coefficient is applied and a second image of the frequency space to which the second correction efficient is applied.

16. The correction device according to claim 13, wherein
the computer system
detects positions of first and second patterns of the reference image,
applies a first window function to an area including the position of the first pattern of the reference image and applies a second window function to an area including the position of the second pattern of the reference image,
acquires a first focusing image obtained by imaging the reference semiconductor pattern in focus on an area corresponding to the position of the first pattern and acquires a second focusing image obtained by imaging the reference semiconductor pattern in focus on an area corresponding to the position of the second pattern,
detects a position of a pattern of the first focusing image and detects a position of a pattern of the second focusing image, and
applies the first window function to an area including a position of a pattern corresponding to the first pattern of the first focusing image and applies the second window function to an area including a position of a pattern corresponding to the second pattern of the second focusing image, and
the image correction values include a first correction coefficient calculated based on the reference image to which the first window function is applied and the first focusing image to which the first window function is applied, and a second correction coefficient calculated based on the reference image to which the second window function is applied and the second focusing image to which the second window function is applied.

17. The correction device according to claim 16, wherein
the computer system
detects a position of a third pattern corresponding to the first pattern of the target image and detects a fourth pattern corresponding to the second pattern of the target image,
applies the first window function to an area including a position of the third pattern of the target image and applies the second window function to an area including a position of the fourth pattern of the target image, and
corrects the target image to which the first window function is applied using the first correction coefficient and corrects the target image to which the second window function is applied using the second correction coefficient.

18. The correction device according to claim 11, wherein the computer system displays an environment setting screen for designating the number of the plurality of image correction values.

19. The correction device according to claim 11, wherein
the computer system
acquires a plurality of reference images obtained by imaging a reference semiconductor pattern at random focus positions a plurality of times, and
acquires a plurality of first focusing images obtained by imaging the reference semiconductor pattern in focus on a first position a plurality of times and acquires a plurality of second focusing images obtained by imaging the reference semiconductor pattern in focus on a second position different from the first position a plurality of times, and
the plurality of image correction values include a first correction coefficient calculated based on the plurality of reference images and the plurality of first focusing images and a second correction coefficient calculated based on the plurality of reference images and the plurality of second focusing images.

20. The correction device according to claim 13, wherein the plurality of image correction values are image correction values calculated based on an image of the reference semiconductor pattern captured by a device different from a device capturing the target image.

21. The correction method according to claim 6, wherein
the position of the first pattern is any position of an edge, a contour line, and a white band of the first pattern, and
the position of the second pattern is any position of an edge, a contour line, and a white band of the second pattern.
